(19) United States
(12) Patent Application Publication
(10) Pub. No.: US 2011/0132460 A1
(43) Pub. Date: Jun. 9, 2011

(54) ACTIVE MATERIALS FOR PHOTOELECTRIC DEVICES AND DEVICES THAT USE THE MATERIAL

(76) Inventors: Yang Yang, Los Angeles, CA (US); Jianhui Hou, Los Angeles, CA (US); Hsiang-Yu Chen, Los Angeles, CA (US)

(21) Appl. No.: 13/056,871

(22) PCT Filed: Aug. 18, 2009
(86) PCT No.: PCT/US09/54173

§ 371 Date: Jan. 31, 2011

Related U.S. Application Data
(60) Provisional application No. 61/089,797, filed on Aug. 18, 2008.

(51) Int. Cl. H01L 51/46; C08F 28/06; C08L 41/00; C07D 333/50; H01L 51/30; B82Y 99/00

(52) U.S. Cl. 136/263; 526/257; 524/547; 549/4; 257/40; 977/734; 257/E51.027

(57) ABSTRACT

A conjugated polymer has a repeated unit having the structure of formula (I) where in n is an integer greater than 1, R₁ and R² are independently selected from alkyl groups with up to 18C atoms, aryls and substituted aryls, and wherein Ar is selected from monocyclic, bicyclic and polycyclic arylene, or monocyclic, bicyclic and polycyclic heteroarylene, or may contain one to five such groups, either fused or linked.

### CROSS-REFERENCE OF RELATED APPLICATION

This application claims priority to U.S. Provisional Application No. 61/089,797 filed Aug. 18, 2008, the entire content of which is hereby incorporated by reference.

### BACKGROUND

1. Field of Invention

Embodiments of this invention relate to active materials for electro-optic devices and electro-optic devices that use the materials; and more particularly to conjugated polymers as active layer materials for electro-optic devices.

2. Discussion of Related Art

The contents of all references cited herein, including articles, published patent applications and patents are hereby incorporated by reference.

Electronic devices based on organic materials (small molecules and polymers) have attracted broad interest. Such devices include organic light emitting devices (OLEDs) (Tang, C. W.; VanSlyke, S. A.; Appl. Phys. Lett. 1987, 51, 913), organic photovoltaic cells (OPVs) (Tang, C. W. Appl. Phys. Lett. 1986, 48, 183), transistors (Bao, Z.; Lovinger, A. J.; Dodabalapur, A. Appl. Phys. Lett. 1996, 69, 3066), bistable devices and memory devices (Ma, L. P.; Liu, J.; Yang, Y. Appl. Phys. Lett. 2002, 80, 2997), etc. Some of the most salient attributes of polymer electronics is that they can be very low-cost, flexible, operate with low-energy consumption, can be produced with high-throughput processing, and can be versatile for applications (Forrest, S. R. Nature 2004, 428, 911). To fulfill the requirement of low cost, a solution process is highly desirable.

Solar cells, also known as photovoltaic (PV) cells or devices, generate electrical power from incident light. The term “light” is used broadly herein to refer to electromagnetic radiation which may include visible, ultraviolet and infrared light. Traditionally, PV cells have been constructed of a number of inorganic semiconductors, e.g., crystalline, polycrystalline and amorphous silicon, gallium arsenide, cadmium telluride and others. More recently, PV cells have been constructed using organic materials.

Solar cells are characterized by the efficiency with which they can convert incident solar power to useful electric power. Devices utilizing crystalline or amorphous silicon dominate commercial applications, and some have achieved efficiencies of 23% or greater. However, efficient crystalline-based devices, especially of large surface area, are difficult and expensive to produce due to the problems inherent in producing large crystals without significant efficiency-degrading defects. On the other hand, high efficiency amorphous silicon devices still suffer from problems with stability. Present commercially available amorphous silicon cells have stabilized efficiencies between 4 and 8%. More recent efforts have focused on the use of organic photovoltaic cells to achieve acceptable photovoltaic conversion efficiencies with economical production costs as well as other possible advantageous properties.

PV devices produce a photo-generated voltage when they are connected across a load and are irradiated by light. When irradiated without any external electronic load, a PV device generates its maximum possible voltage, V open-circuit, or V_{OC}. If a PV device is irradiated with its electrical contacts shorted, a maximum short-circuit current, or I_{SC}, is produced. (Current is conventionally referred to as “I” or “J”.) When actually used to generate power, a PV device is connected to a finite resistive load in which the power output is given by the product of the current and voltage, I×V. The maximum total power generated by a PV device is inherently incapable of exceeding the product I_{SC}×V_{OC}. When the load value is optimized for maximum power extraction, the current and voltage have values, Iₘₐₓ and Vₘₐₓ, respectively. A figure of merit for solar cells is the fill factor, ff (or FF), defined as:

$$ff = \frac{{I}_{max} {V}_{max}}{{I}_{SC} {V}_{OC}}$$

where ff is always less than 1, as I_{SC} and V_{OC} are never achieved simultaneously in actual use. Nonetheless, as ff approaches 1, the device is more efficient.

When electromagnetic radiation of an appropriate energy is incident upon a semiconductive organic material, for example, an organic molecular crystal (OMC) material, or a polymer, a photon can be absorbed to produce an excited molecular state. This energy absorption is associated with the promotion of an electron from a bound state in the highest occupied molecular orbital (HOMO) to the lowest unoccupied molecular orbital (LUMO), or equivalently, the promotion of a hole from the LUMO to the HOMO. In organic thin-film photoconductors, the generated excited state is believed to be an exciton, i.e., an electron-hole pair in a bound state which is transported as a quasi-particle. The excitons can have an appreciable life-time before recombination. To produce a photocurrent the electron-hole pair must become separated, for example at a donor-acceptor interface between two dissimilar contacting organic thin films. The interface of these two materials is called a photovoltaic heterojunction. If the charges do not separate, they can recombine with each other (known as quenching) either radiatively, by the emission of light of a lower energy than the incident light, or non-radiatively, by the production of heat. Either of these outcomes is undesirable in a PV device. In traditional semiconductor theory, materials for forming PV heterojunctions have been denoted as generally being of either n (donor) type or p (acceptor) type. Here n-type denotes that the majority carrier type is the electron. This could be viewed as the material having many electrons in relatively free energy states. The p-type denotes that the majority carrier type is the hole. Such material has many holes in relatively free energy states. The type of the background majority carrier concentration depends primarily on unintentional doping by defects or impurities. The type and concentration of impurities determine the value of the Fermi energy, or level, within the gap between the highest occupied molecular orbital (HOMO) and the lowest unoccupied molecular orbital (LUMO), called the HOMO-LUMO gap. The Fermi energy characterizes the statistical occupation of molecular quantum energy states denoted by the value of energy for which the probability of occupation is equal to ½. A Fermi energy near the LUMO energy indicates that electrons are the predominant carrier. A Fermi energy near the HOMO energy indicates that holes are the predominant carrier. Accordingly, the Fermi energy is a primary characterizing property of traditional semiconductors and the PV heterojunction has traditionally been the p-n interface.

A significant property in organic semiconductors is carrier mobility. Mobility measures the ease with which a charge carrier can move through a conducting material in response to an electric field. As opposed to free carrier concentrations, carrier mobility is determined in large part by intrinsic properties of the organic material such as crystal symmetry and periodicity. Appropriate symmetry and periodicity can produce higher quantum wavefunction overlap of HOMO levels producing higher hole mobility, or similarly, higher overlap of LUMO levels to produce higher electron mobility. Moreover, the donor or acceptor nature of an organic semiconductor may be at odds with the higher carrier mobility. The result is that device configuration predictions from donor/acceptor criteria may not be borne out by actual device performance. Due to these electronic properties of organic materials, the nomenclature of “hole-transporting-layer” (HTL) or “electron-transporting-layer” (ETL) is often used rather than designating them as “p-type” or “acceptor-type” and “n-type” or “donor-type”. In this designation scheme, an ETL will be preferentially electron conducting and an HTL will be preferentially hole transporting.

Organic PV cells have many potential advantages when compared to traditional silicon-based devices. Organic PV cells are light weight, economical in the materials used, and can be deposited on low cost substrates, such as flexible plastic foils. However, organic PV devices typically have relatively low quantum yield (the ratio of photons absorbed to carrier pairs generated, or electromagnetic radiation to electricity conversion efficiency), being on the order of 1% or less. This is, in part, thought to be due to the second order nature of the intrinsic photoconductive process. That is, carrier generation requires exciton generation, diffusion and ionization. However, the diffusion length (L_{D}) of an exciton is typically much less than the optical absorption length, requiring a trade off between using a thick, and therefore resistive, cell with multiple or highly folded interfaces, or a thin cell with a low optical absorption efficiency.

Conjugated polymers are polymers containing π-electron conjugated units along the main chain. They can be used as active layer materials for some types of photo-electric devices, such as polymer light emitting devices, polymer solar cells, polymer field effect transistors, etc. As polymer solar cell materials, conjugated polymers should possess some properties, such as high mobility, good harvest of sunlight, good processibility, and proper molecular energy level. Some conjugated polymers have proven to be good solar cell materials. For example, some derivatives of poly(p-phenylene vinylene), such as MEH-PPV and MDMO-PPV, and some derivatives of poly(3-alkyl-thiophene), such as P3HT and P3OT, and some conjugated polymers with heterocyclic aromatic rings, such as poly[2,6-(4,4-bis-(2-ethylhexyl)-4H-cyclopenta[2,1-b;3,4-bl-dithiophene)-alt-4,7-(2,1,3-benzothiadiazole)] (PCPDTBT), have been successfully used as photo-active layer materials. Although the energy conversion efficiencies of solar cell devices based on these polymers have reached up to 4˜5%, this is much lower than that of inorganic semiconductor solar cells. Therefore, there is accordingly a need in the art for conjugated polymers that have improved photovoltaic effects.

### SUMMARY

A conjugated polymer according to an embodiment of the current invention has a repeated unit having the structure of formula (I)

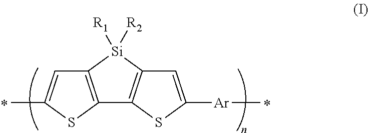

wherein n is an integer greater than 1,

wherein R₁ and R₂ are independently selected from alkyl groups with up to 18 C atoms, aryls and substituted aryls, and

wherein Ar is selected from monocyclic, bicyclic and polycyclic arylene, or monocyclic, bicyclic and polycyclic heteroarylene, or may contain one to five such groups, either fused or linked.

An electronic or electro-optic device according to an embodiment of the current invention includes a conjugated polymer material according to an embodiment of the current invention.

An electronic or electro-optic device according to an embodiment of the current invention has a first electrode, a second electrode spaced apart from the first electrode, and a layer of active material disposed between the first electrode and the second electrode. The active layer includes a conjugated polymer according to an embodiment of the current invention.

### BRIEF DESCRIPTION OF THE DRAWINGS

The invention may be better understood by reading the following detailed description with reference to the accompanying figures in which:

FIG. 1 is a schematic illustration of an electro-optic device according to an embodiment of the current invention;

FIG. 2 is a schematic illustration of an electro-optic device according to another embodiment of the current invention;

FIG. 3 shows current density versus bias voltage data of a polymer solar cell according to an embodiment of the current invention; and

FIG. 4 shows electron quantum efficiency of a polymer solar cell according to an embodiment of the current invention compared to a conventional device.

### DETAILED DESCRIPTION

In describing embodiments of the present invention, specific terminology is employed for the sake of clarity. However, the invention is not intended to be limited to the specific terminology so selected. It is to be understood that each specific element includes all technical equivalents which operate in a similar manner to accomplish a similar purpose.

Conjugated polymer materials for polymer solar cell should have high mobility, so the main chains of the conjugated polymers should have a planar structure according to some embodiments of the current invention. This can also be helpful to form π-π stacking structures and facilitate charge transfer between two adjacent main chains. Such materials should have a low band gap to provide good harvesting of sunlight; they also should have proper molecular energy levels that match with electrode and electron acceptor materials in polymer solar cell devices. It thus would be desirable according to some embodiments of the current invention to provide conjugated polymers as photovoltaic materials that possess some or all of the properties mentioned above.

### DEFINITIONS AND NOMENCLATURE

Unless otherwise indicated, this invention is not limited to specific starting materials, regents or reaction conditions, as such may vary. The term “alkyl” as used herein refers to a branched or unbranched saturated hydrocarbon group typically, although not necessarily, containing 1 to 18 carbon atoms, such as methyl, ethyl, n-propyl, isopropyl, n-octyl, isooctyl, 2-ethyl-hexyl, decyl, and the like, as well as cycloalkyl groups such as cyclopentyl, cyclohexyl and the like. The term “heteroarylene” as used herein refers to a hydrocarbon arylene in which one or more carbon atoms are replaced with a “heteroatom” other than carbon, e.g., nitrogen, oxygen, sulfur, silicon, selenium, phosphorus. The term “N-containing heteroarylene” as used herein refers to a heteroarylene in which one or more “heteroatom” defined above are nitrogen atoms. The term “substituted” as in “substituted arylene”, “substituted heteroarylene”, and the like, is meant that in the arylene or heteroarylene, or other moiety, at least one hydrogen atom bound to a carbon (or other) atom is replaced with one or more non-hydrogen substituents. Such substituents include, but are not limited to, functional groups such as halo, hydroxyl, alkylthio, alkoxy, aryloxy, alkylcarbonyl, acyloxy, nitro, cyano, and the like.

Polymers according to some embodiments of the current invention are comprised of repeated units having the general structure of formula (I)

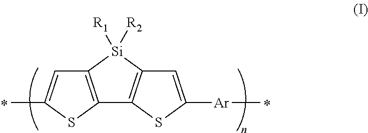

wherein n is an integer greater than 1. R₁ and R₂ are independently selected from alkyl groups with up to 18 C atoms, aryls and substituted aryls. Ar is selected from the group consisting of monocyclic, bicyclic and polycyclic arylene, or monocyclic, bicyclic and polycyclic heteroarylene, or may contain one to five, typically one to three such groups, either fused or linked. In certain embodiments, R₁ and R₂ are both 2-ethyl-hexyl.

Examples of suitable Ar moieties include, but are not limited to, the following:

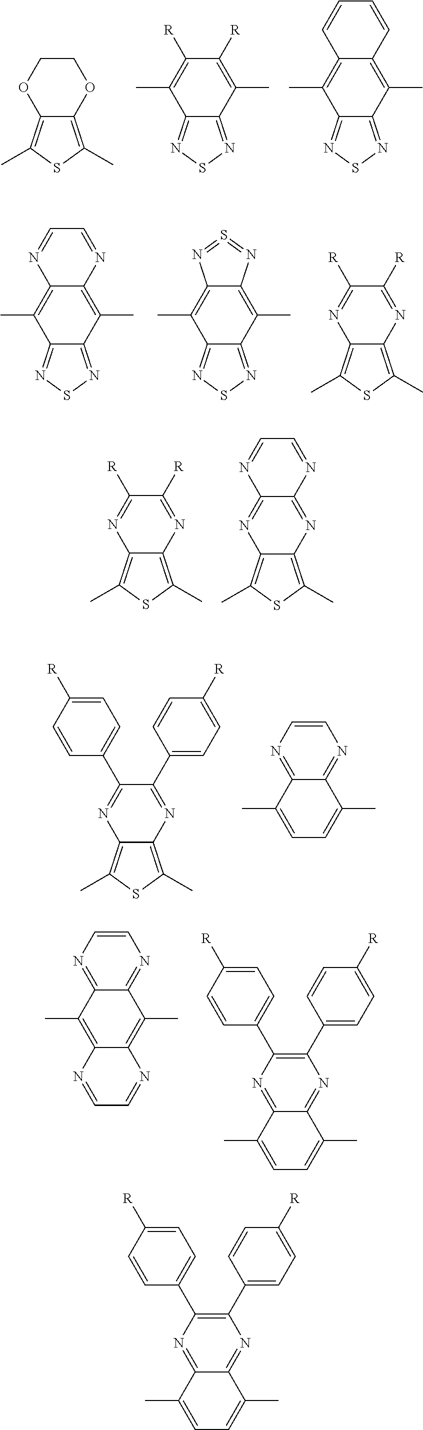

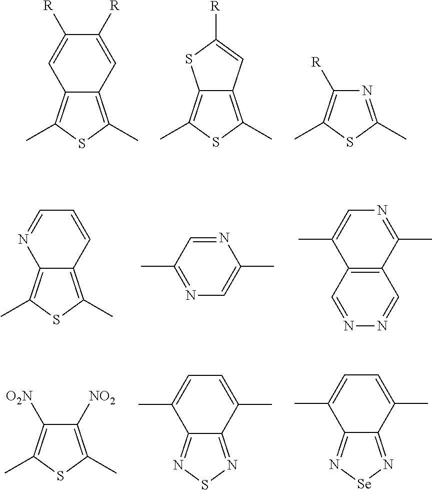

In the above structures, R is a proton or alkyl group with carbon atom number of 1-18.

Polymers according some embodiments of formula (I) are comprised of repeated units wherein R₁ and R₂ are alkyl groups with carbon atom number of 4-18, and Ar is N-containing heteroarylene, but are not limited to, the following:

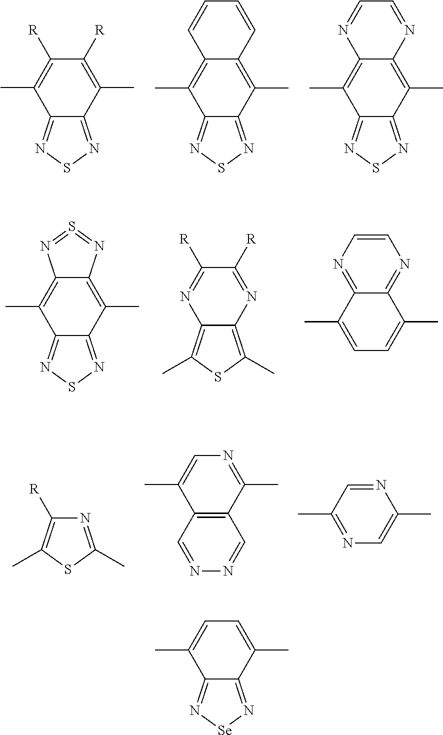

In the above structures, R is a proton or alkyl group with carbon atom number of 1-18.

In other embodiments, the polymers of formula (I) are comprised of repeated units as formula (II), wherein n is an integer greater than 1, R₁ and R₂ are alkyl groups with carbon atom number of 6-12, and Ar is 4,7-diyl-benzo[c][1,2,5]thiadiazole.

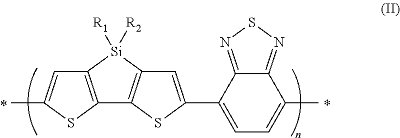

Typically, the number average molecular weight of the polymers is in the range of approximately 1000 to 1,000,000, which can further have a number average molecular weight in the range of about 5000 to 500,000, and can further have a number average molecular weight in the range of approximately 20,000 to 200,000. It will be appreciated that molecular weight can be varied to optimize polymer properties. For example, lower molecular weight is can ensure solubility, while a higher molecular weight can ensure good film-forming properties.

### Monomers:

Other embodiments of the invention include compounds having the structure shown below

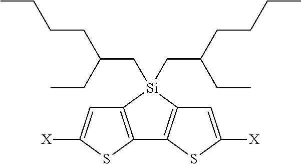

wherein X is I, Br, Cl, trialkylsilyl, including but not limited to trimethylsilyl, triethylsilyl, triisopropylsilyl, and t-butyldimethylsilyl, boronic acid, boronic acid esters including, but not being limited to, 1,3,2-dioxaborinane-2-yl, 4,4,5,5-tetramethyl-1,3,2-dioxaborolane-2-yl, and 5,5-dimethyl-1,3,2-dioxaborinane-2-yl, magnesium halide including magnesium chloride (—MgCl), magnesium bromide (—MgBr), and magnesium iodide (MgI), or zinchalide groups including zincchloride (—ZnCl) and zincbromide (—ZnBr), or trialkyltin groups including, but not being limited to, trimethyl tin (—Sn(Me)₃), triethyl tin (—Sn(Et)₃), and tributyl tin (—Sn(Bu)₃).

Compounds according to the present invention can be prepared, for example, according to the scheme shown below

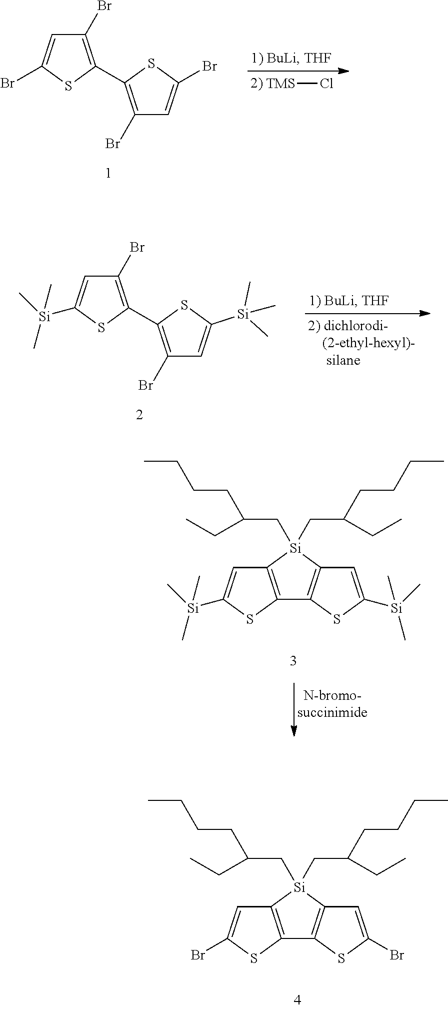

For example, according to the scheme above, compound 1 (Heterocycles; 1991(32), 1805-1812) is reacted with butyllithium and trimethylsilyl chloride to prepare compound 2. Other trialkylsilyl halides may be substituted for trimethylsilyl chloride. Compound 2 is then reacted with butyllithium and dichlorodi(2-ethyl-hexyl)silane to form compound 3. Compound 3 may be reacted with N-bromosuccinimide, produce compound 4. Other N-halosuccinimides may be substituted for N-bromosuccinimide. Compound 4 can then be converted into boronic acids, boronic esters, magnesium halides, zinc halides, or trialkyl tin compounds according to procedures known in the art.

Compounds according to the invention may be used to as monomers to prepare polymers according to the invention, or to make monomers for polymerization according to the invention.

### Polymerization:

Polymers according to some embodiments of the current invention are generally synthesized by co-polymerizing monomers having the structure of formula (III) and formula (IV),

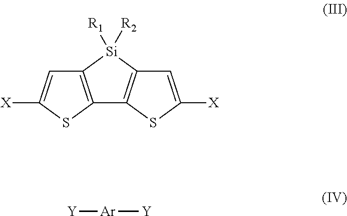

wherein for formula (III) and formula (IV): R₁, R₂, A1, A2 and Ar are as defined above; X is dependently selected on Y. If Y is selected from a boronic acid group, or boronic acid esters groups including, but not being limited to, 1,3,2-dioxaborinane-2-yl, 4,4,5,5-tetramethyl-1,3,2-dioxaborolane-2-yl, and 5,5-dimethyl-1,3,2-dioxaborinane-2-yl, or magnesium halide groups including magnesium chloride, magnesium bromide, and magnesium iodide, or zinchalide groups including zincchloride and zincbromide, or trialkyltin groups including, but not being limited to, trimethyl tin, triethyl tin, and tributyl tin, X should be selected from I, Br, or Cl, and if Y is selected from I, Br, or Cl, X should be selected from a boronic acid group, or boronic acid esters groups including, but not being limited to, 1,3,2-dioxaborinane-2-yl, 4,4,5,5-tetramethyl-1,3,2-dioxaborolane-2-yl, and 5,5-dimethyl-1,3,2-dioxaborinane-2-yl, or magnesium halide groups including magnesium chloride, magnesium bromide, and magnesium iodide, or zinchalide groups including zincchloride and zincbromide, or trialkyltin groups including, but not being limited to, trimethyl tin, triethyl tin, and tributyl tin.

A polymerization route of polymers according to some embodiments of the current invention using monomers as mentioned in formula (III) and (IV) is according to the following scheme:

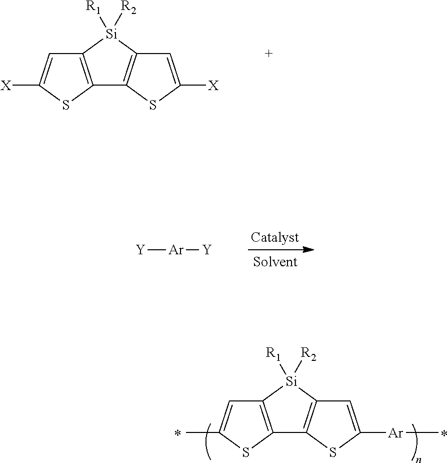

wherein: n, A1, A2, R₁, R₂, Ar, X, and Y are defined as above.

If the condensation polymerization reaction is conducted between a dimagnesiohalo-arene compound and an arene dihalide compound, the polymerization reaction is a typical ‘McCullough method’, as reported by McCullough and Lowe [J. Chem. Soc., Chem. Commun. 1992, 70.]. In McCullough method, THF is used as a solvent commonly, and a mixture of toluene and THF can sometimes also be used. Some catalysts containing Pd or Ni, preferably[1,3-bis(diphenylphosphino)propane]dichloronickel(II) and tetrakis(triphenylphosphine)palladium(0), can be used as catalyst for this reaction, and the molar ratio between catalyst and starting material is in the range of 10-0.1%. The reaction is typically conducted at about 10° C. to the refluxing point of the solvent. Depending on the reactivities of the reactants, the polymerization may take 30 minutes to 24 hours. Dimagnesiohalo-arene used in this reaction can be prepared from Grignard metathesis reaction, as reported by Loewe and McCullough [Macromolecules, 2001, (34), 4324-4333], or reaction between arene dihalide and magnesium.

In some particular embodiments, arene dihalide and Dimagnesiohalo-arene used in the ‘McCullough method’ for the polymers of the invention are arene dibromide and dimagnesiobromo-arene.

If the condensation polymerization reaction is conducted between a dizinchalo-arene compound and an arene dihalide compound, the polymerization reaction is a typical ‘Rieke method’, as reported by Chen and Rieke [Synth. Met. 1993, (60), 175.]. In this method, THF is used as a solvent commonly, and some catalysts containing Pd or Ni, preferably [1,2-Bis(diphenylphosphino) ethane]dichloronickel(II), can be used as a catalyst for this reaction, and the molar ratio between catalyst and starting material is in the range of 10-0.1%. The reaction is typically conducted at about 10° C. to the refluxing point of the solvent. Depending on the reactivities of the reactants, the polymerization may take 30 minutes to 24 hours. In some particular embodiments, arene dihalide and dizinchalo-arene used in the ‘Rieke method’ for the polymers of embodiments of the invention are arene dibromide and dizincchloro-arene.

If the condensation polymerization reaction is conducted between a bis(trialkylstannyl)-arene compound and an arene dihalide, the polymerization reaction is a typical ‘Stille coupling method’, as reported by Iraqi and Barker [J. Mater. Chem. 1998, (8) 25]. In this method, many kinds of solvents including, but not limited to, tetrahydrofuran (THF), Dimethyl Formamide (DMF), and toluene can be used as a solvent commonly, and some catalysts containing Pd, preferably tetrakis(triphenylphosphine)palladium(0), can be used as a catalyst for this reaction, and the molar ratio between catalyst and starting material is in the range of 10-0.1%. The reaction is typically conducted at about 60° C. to the refluxing point of the solvent. Depending on the reactivities of the reactants, the polymerization may take 1 to 72 hours.

In some particular embodiments of the current invention, arene dihalide and bis(trialkylstannyl)-arene used in the ‘Stifle coupling method’ for the polymers of the invention are arene dibromide and bis(tributylstannyl)-arene.

If the condensation polymerization reaction is conducted between an arene-diboronic acid compound or an arene-diboronic acid ester compound and an arene dihalide, the polymerization reaction is a typical ‘Suzuki reaction’, as reported by Miyaura and Suzuki [Chemical reviews 1995 (95): 2457-2483]. In this method, many kinds of solvents including, but not limited to, THF, and toluene can be used as a solvent commonly, and some catalysts containing Pd, preferably tetrakis(triphenylphosphine)palladium(0), can be used as a catalyst for this reaction, and the molar ratio between catalyst and starting material is in the range of 10-0.1%. The reaction is typically conducted at about 60° C. to the refluxing point of the solvent. Depending on the reactivities of the reactants, the polymerization may take 12 to 72 hours.

In some particular embodiments of the current invention, arene dihalide used in ‘Suzuki reaction’ for the polymers of the invention is arene dibromide.

Generally, the polymers according to some embodiments of the invention are useful in any application wherein a conjugated polymer, particularly a conjugated photovoltaic polymer, would have utility. For example, the present polymers can be suitable as the active materials in the following devices: thin film semiconductor devices such as solar cells, light emitting diodes, transistors, photodetectors, and photoconductors; electrochemical devices such as rechargeable batteries, capacitors, supercapacitors, and electrochromic devices, and sensors.

### Other

Semiconductive compositions may be prepared that comprise a polymer according to an embodiment of the invention optionally combined with an admixer, typically a compound selected such that charge and/or energy transfer takes place between the admixer and the polymer when an excitation source including light or voltage is applied across the composition. For example, the admixer can be fullerene such as: C₆₀, C₇₀, or C₈₀, or some substituted fullerene compounds such as PCBM ([6,6]-phenyl C₆₁ butyric acid methyl ester) and PCBB ([6,6]-phenyl C₇₁ butyric acid butyl ester). Polymers according to some embodiments of the invention are particularly useful as photovoltaic materials in photovoltaic devices such as photodetector devices, solar cell devices, and the like. Photovoltaic devices, including solar cell devices, are generally comprised of laminates of a suitable photovoltaic material between a hole-collecting electrode layer and an electron-collecting layer. Additional layers, elements or a substrate may or may not be present.

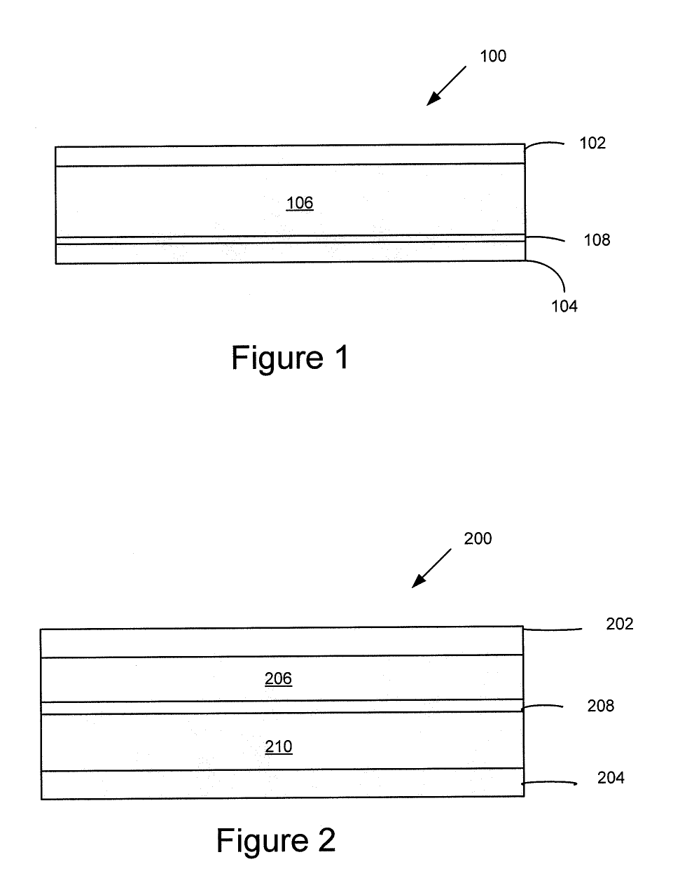

FIG. 1 is a schematic illustration of an electro-optic device 100 according to an embodiment of the current invention. The electro-optic device 100 has a first electrode 102, a second electrode 104 spaced apart from the first electrode 102, and an active layer 106 disposed between the first electrode and the second electrode. The electro-optic device 100 can have multiple layers of active materials and/or layers of material between the electrodes and the active layer such as the layer 108, for example. The active layer can include a conjugated polymer material according to one or more embodiments of the current invention. One or both of the electrodes 102 and 104 can be transparent electrodes in some embodiments of the current invention.

FIG. 2 is a schematic illustration of an electro-optic device 200 according to another embodiment of the current invention. The electro-optic device 200 has a first electrode 202, a second electrode 204 spaced apart from the first electrode 202, and an active layer 206 disposed between the first electrode and the second electrode. This embodiment is an example of an electro-optic device that has a second active layer 210 between the first electrode 202 and the second electrode 204. The electro-optic device 200 can have additional layers of material between the active layers and the electrodes and/or between the two active layers. For example, there could be a layer 208 between the active layers 206 and 210. Devices according to the current invention are not limited to only one or two active layers; they may have multiple active layers in some embodiments of the current invention. For example, the device 200 can be, but is not limited to, a tandem photovoltaic cell that has two or more active layers with thin interfacial layers. The schematic illustrations of FIGS. 1 and 2 are shown as examples. Devices according to other embodiments of the current invention are not limited to these specific examples.

### EXPERIMENTAL

The practice of the present invention can employ conventional techniques of polymer chemistry, which are within the skill of the art. In the following examples, efforts have been made to ensure accuracy with respect to numbers used, including amounts, temperature, reaction time, etc., but some experimental error and deviation should be accounted for. Temperature used in the following examples is in degrees C., and the pressure is at or near atmospheric. All solvents were purchased as HPLC grade, and all reactions were routinely conducted under an inert atmosphere of argon. All regents were obtained commercially unless otherwise indicated.

### Example 1

### Synthesis of poly(3,3′-bis(2-ethyl-hexyl)-silylene-2,2′-bithiophene-5,5′-diyl)-alt-benzo[c][1,2,5]thiadiazole, HSi-1

The synthesis route of this polymer, HSi-1 is shown in the following scheme.

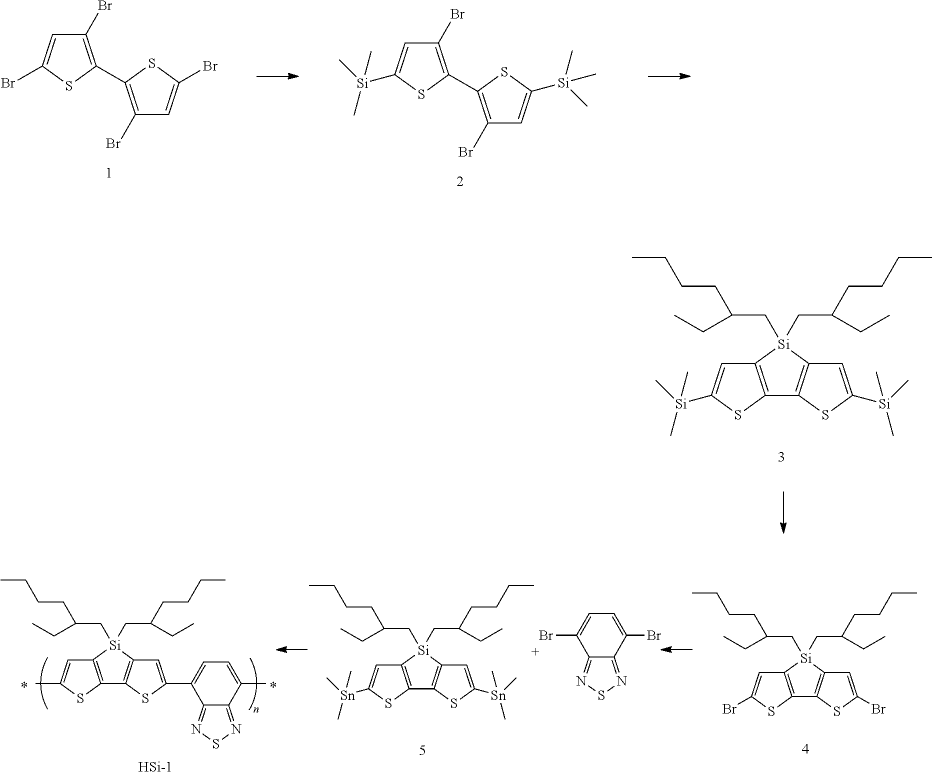

4.78 g (10 mmol) of 3,3′,5,5′-tetrabromo-2,2′-bithiophene, compound 1 in the above scheme, synthesized by the reported method [Heterocycles; 1991(32), 1805-1812] was dissolved into 150 ml ultra dry THF, and the solution was cooled down to −90° C. by a liquid nitrogen-methanol bath and stirred for 15 minutes. Then, 8 ml butyllithium solution in hexane (2.5 mol/L) was added dropwise in 1 hour, and the reactant was stirred for another 15 minutes. Subsequently, 2.7 g chlorotrimethylsilane (25 mmol) was added in one portion, and temperature of the reactant was raised to ambient temperature by removal of the cooling bath. Then, the reactant was poured into water and extracted by ethyl ether several times. The volatile materials were removed under vacuum. The residue was purified by recrystallization using ethanol as solvent and yielded 3.3 g of 3,3′-dibromo-5,5′-bis(trimethylsilyl)-2,2′-bithiophene (yield 71%), compound 2, as a white solid.

Compound 2 (2.34 g, 5 mmol) and 20 ml THF were put into a flask, and cooled down to −78° C. by a liquid nitrogen-acetone bath and stirred for 15 minutes. Then, 4 ml butyllithium solution in hexane (2.5 mol/L) was added dropwise in 5 minutes, and the reactant was stirred for another 15 minutes at that temperature. Subsequently, 1.95 g dichlorodi(2-ethyl-hexyl)silane (6 mmol) was added in one portion, and the cooling bath was removed and the reactant was stirred for 2 hours under ambient temperature. Then, the reactant was poured into water and extracted by ethyl ether several times. The volatile materials were removed under vacuum. The residue was purified by silica gel chromatography using hexane as solvent and yielded 2.26 g of 3,3′-bis(2-ethyl-hexyl)-silyene-5,5′-bis(trimethylsilyl)-2,2′-bithiophene (yield 72%), compound 3, as a colorless oil.

Compound 3 (1.69 g, 3 mmol) was dissolved into 20 ml THF, and N-bromosuccinimide (1.1 g, 6.17 mmol) was added in one portion. The reactant was stirred at ambient temperature for 4 hours, and then extracted by diethyl ether. The volatile materials were removed under vacuum, and the residue was purified by silica gel chromatography using hexane as eluent. 3,3′-Bis(2-ethyl-hexyl)-silyene-5,5′-dibromo-2,2′-bithiophene (1.37 g, 2.9 mmol) compound 4 was obtained as sticky colorless oil with a yield of 96%.

Compound 4 (1.2 g, 2.51 mmol) and 20 ml ultra dry THF were put into a flask. The clear solution was cooled down to −78° C. by a liquid nitrogen-acetone bath. Then, 2.6 ml butyllithium solution in hexane (6.5 mmol, 2.5 mol/L) was added dropwise. After stirring at −78° C. for 15 minutes, 7 ml trimethyltin chloride was added in one portion, and then the cooling bath was removed. After being stirred at ambient temperature for two hours, the reactant was poured into cool water and extracted by diethyl ether several times. After removal of volatile materials, 3,3′-Bis(2-ethyl-hexyl)-silyene-5,5′-bis(trimethyltin)-2,2′-bithiophene (1.78 g, 2.39 mmol), compound 5, was obtained as a sticky pale green oil with a yield of 95.6% and used without any further purification.

4,7-dibromo-benzo[c][1,2,5]thiadiazole (0.681 g, 2.32 mmol) and compound 5 (1.78 g, 2.39 mmol) were dissolved into 100 ml toluene. The mixture was purged by argon for 10 minutes, then 60 mg of Pd(PPh3)4 was added. After being purged with argon for 20 minutes, the oil bath was heated to 110° C. carefully, and the reactant was stirred for 24 hours at this temperature under argon atmosphere. Then, the reactant was cooled to room temperature and the polymer was precipitated by addition of 100 ml methanol, and filtered through a Soxhlet thimble, which was then subjected to Soxhlet extraction with methanol, hexane, and chloroform. The polymer was recovered from the chloroform fraction by rotary evaporation. The solid was dried under vacuum for 1 day to get poly(3,3′-bis(2-ethyl-hexyl)-silylene-2,2′-bithiophene-5,5′-diyl)-alt-benzo[c][1,2,5]thiadiazole, HSi-1.

### Example 2

### Fabrication and Characterization of Polymer Solar Cell Device Using HSi as Active Layer Material

The polymer, HSi, (30 mg) was dissolved in chlorobenezene to make 20 mg ml⁻¹ solution, followed by blending with PCBM in 60 wt. %.

Polymer solar cell devices were fabricated on a transparent, indium-tin oxide (ITO) coated glass substrate. A thin layer of a conducting polymer, poly(styrenesulfonate) doped poly(3,4-ethylenedioxy-thiophene) (PEDOT:PSS), was spin-coated onto the ITO surface for a better interface. The thickness of the PEDOT:PSS layer was about 30 nm, measured with Dektek profilometer. Then, a thin layer was spin-coated using the solution prepared above. Then, thin layers of calcium and aluminum were evaporated successively at pressure around 10⁻⁴ Pa. Testing was performed in a N₂ filled glove box under AM 1.5G irradiation (100 mW cm⁻²) using a Xenon lamp solar simulator calibrated with a silicon diode (with KG5 visible filter) calibrated in National Renewable Energy Laboratory (NREL).

The power conversion efficiency of the best polymer solar cell device was 3.5%, with an open circuit voltage of 0.66V, a short circuit current of 10 mA/cm², and a fill factor of 53%.

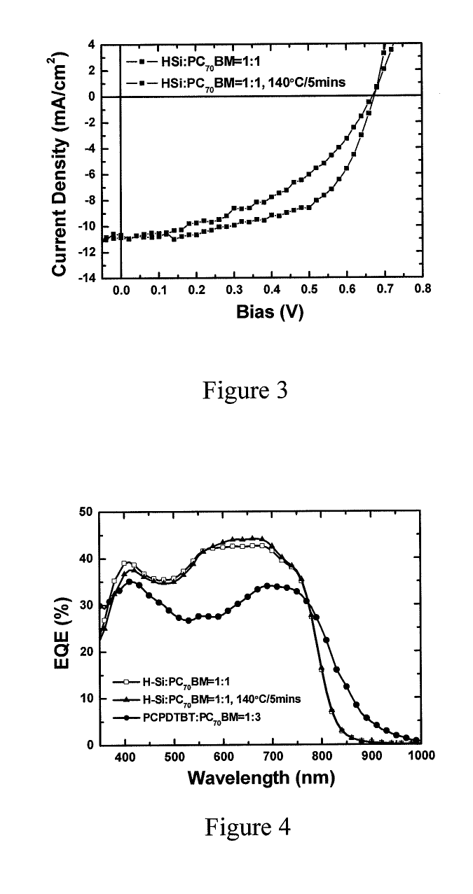

FIG. 3 shows I-V curve data of a polymer solar cell device under simulate sunlight (AM 1.5, 100 mW/cm²) with a structure of ITO/PEDOT:PSS/HSi:PCBM (1:1 wt/wt)/Ca/Al according to an embodiment of the current invention. Annealing the polymer blend film significantly increase the FF without decrease in Voc and Jsc.

FIG. 4 shows IPCE curve data of a polymer solar cell device with a structure of ITO/PEDOT:PSS/HSi:PCBM (1:1 wt/wt)/Ca/Al according to an embodiment of the current invention. These devices efficiently harvest photons with wavelength from 350˜800 nm. Compared with its counterpart, PCPDTBT, the EQE in the absorption peak region (500˜800 nm) is much higher.

The current invention was described with reference to particular embodiments and examples. However, this invention is not limited to only the embodiments and examples described. One of ordinary skill in the art should recognize, based on the teachings herein, that numerous modifications and substitutions can be made without departing from the scope of the invention which is defined by the claims.

1. A conjugated polymer comprising a repeated unit having the structure of formula (I) 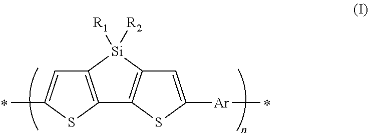
wherein n is an integer greater than 1,
wherein R₁ and R₂ are independently selected from alkyl groups with up to 18 C atoms, aryls and substituted aryls, and
wherein Ar is selected from monocyclic, bicyclic and polycyclic arylene, or monocyclic, bicyclic and polycyclic heteroarylene, or may contain one to five such groups, either fused or linked.

2. The conjugated polymer according to claim 1, wherein R₁ and R₂ are 2-ethyl-hexyl groups.

3. The conjugated polymer according to claim 1, wherein Ar is selected from monocyclic, bicyclic and polycyclic arylene, or monocyclic, bicyclic and polycyclic heteroarylene, or may contain one to three such groups, either fused or linked.

4. The conjugated polymer of claim 1, wherein Ar is selected from the following: 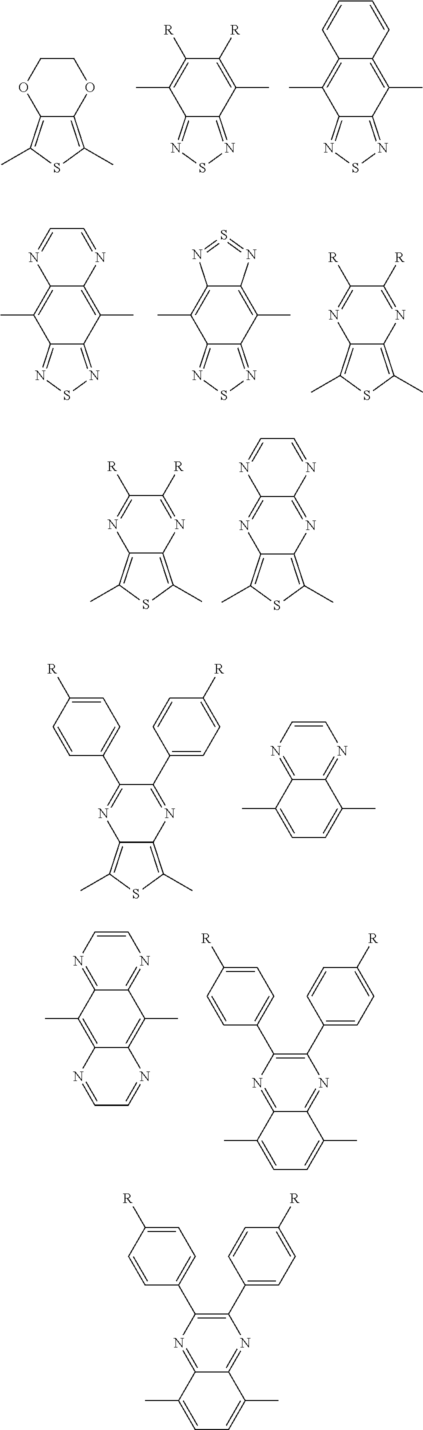 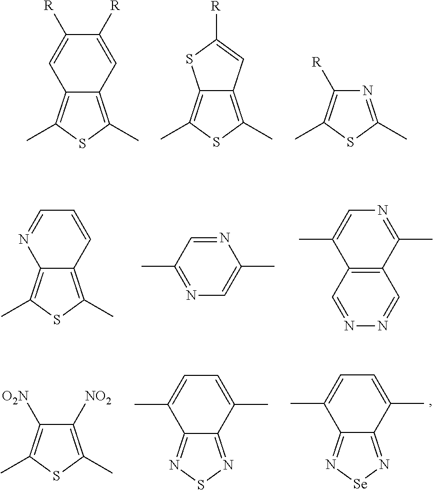
wherein R is a proton or alkyl group with carbon atom number of 1-18.

5. The conjugated polymer of claim 1, wherein the repeated units has the structure of formula (II) 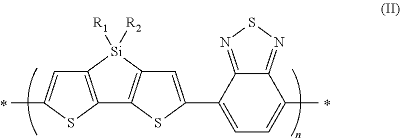
wherein n is an integer greater than 1, R₁ and R₂ are independently selected from alkyl groups with up to 18 C atoms, aryls and substituted aryls.

6. The conjugated polymer of claim 5, wherein the R₁ and R₂ are independently selected from alkyl groups with 4 to 12 C atoms.

7. The conjugated polymer of claim 6, wherein the R₁ and R₂ are 2-ethyl-hexyl groups.

8. An electronic or electro-optic device comprising a conjugated polymer material according to claim 1.

9. The device according to claim 8, wherein said conjugated polymer material is a photovoltaic material.

10. The device according to claim 9, wherein said electronic or electro-optic device is a polymer solar cell device or photodetector device.

11. The device according to claim 10, wherein said device is a polymer solar cell device comprising a bulk heterojunction structure.

12. The device according to claim 11, wherein said bulk heterojunction structure comprises at least one ingredient in addition to said conjugated polymer.

13. The device according to claim 12, wherein said at least one ingredient in addition to said conjugated polymer is at least one of a fullerene or its derivatives.

14. The device according to claim 13, wherein said fullerene or its derivatives is at least one of [6,6]-phenyl C₆₁ butyric acid methyl ester or [6,6]-phenyl C₇₁ butyric acid methyl ester.

15. An electronic or electro-optic device, comprising:
a first electrode;
a second electrode spaced apart from said first electrode; and
a layer of active material disposed between said first electrode and said second electrode,
wherein said active layer comprises a conjugated polymer comprising a repeated unit having the structure of formula (I) 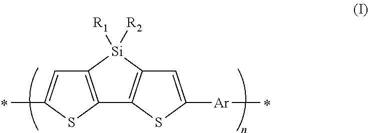
wherein n is an integer greater than 1,
wherein R₁ and R₂ are independently selected from alkyl groups with up to 18 C atoms, aryls and substituted aryls, and
wherein Ar is selected from monocyclic, bicyclic and polycyclic arylene, or monocyclic, bicyclic and polycyclic heteroarylene, or may contain one to five such groups, either fused or linked.

16. An electronic or electro-optic device according to claim 15, further comprising a second layer of active material disposed between said first and second electrodes such that said electronic or electro-optic device is a tandem photovoltaic device.

17. A compound having the structure 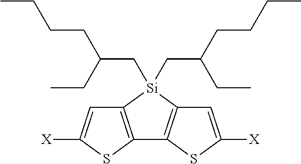
wherein X selected from the group consisting of I, Br, Cl, trialkylsilyl, boronic acid, boronic acid ester, magnesium halide, zinc halide, and trialkyltin.
